(19) United States
(12) Patent Application Publication
(10) Pub. No.: US 2022/0121957 A1
(43) Pub. Date: Apr. 21, 2022

(54) LITHOGRAPHY SIMULATION USING MACHINE LEARNING

(71) Applicant: Synopsys, Inc., Mountain View, CA (US)

(72) Inventors: Xiangyu Zhou, Munich (DE); Martin Bohn, Munich (DE); Mariya Braylovska, Munich (DE)

(21) Appl. No.: 17/467,682

(22) Filed: Sep. 7, 2021

Related U.S. Application Data
(60) Provisional application No. 63/092,417, filed on Oct. 15, 2020.

(51) Int. Cl. G06N 3/08; G06N 3/04

(52) U.S. Cl. CPC G06N 3/088; G06N 3/0454

(57) ABSTRACT

In certain aspects, a quasi-rigorous electromagnetic simulation, such as a domain decomposition-based simulation, is applied to an area of interest of a lithographic mask to produce an approximate prediction of the electromagnetic field from the area of interest. This is then applied as input to a machine learning model, which improves the electromagnetic field prediction from the quasi-rigorous simulation, thus yielding results which are closer to a fully-rigorous Maxwell simulation but without requiring the same computational load.

### RELATED APPLICATION

This application claims priority under 35 U.S.C. § 119(e) to U.S. Provisional Patent Application Ser. No. 63/092,417, “Methodology and Framework for Fast and Accurate Lithography Simulation,” filed Oct. 15, 2020. The subject matter of all of the foregoing is incorporated herein by reference in its entirety.

### TECHNICAL FIELD

This disclosure relates generally to the field of lithography simulation and more particularly to the use of machine learning to improve lithography process modeling.

### BACKGROUND

As semiconductor technology has been continuously advancing, smaller and smaller feature sizes have been necessary for the masks used by the lithography process. Because lithography employs electromagnetic waves to selectively expose areas on the wafer through a lithographic mask, if the dimensions of desired features are smaller than the wavelength of the illuminating source, there can be non-trivial electromagnetic scattering among adjacent features on the mask. Therefore, highly accurate models are needed to account for these effects.

Full-wave Maxwell solvers such as Rigorous Coupled-Wave Analysis (RCWA) or Finite-Difference Time-Domain (FDTD) are rigorous full-wave solutions of Maxwell's equations in three dimensions without approximating assumptions. They account for electromagnetic scattering, but they are computationally expensive. Traditionally, model-order reduction techniques, such as domain decomposition and other approximations to Maxell's equations, may be used to produce an approximate solution within an acceptable runtime. However, there is an increasing accuracy gap between these quasi-rigorous approaches and fully rigorous Maxwell solvers as the feature sizes continue to shrink.

### SUMMARY

In certain aspects, a quasi-rigorous electromagnetic simulation, such as a domain decomposition-based simulation, is applied to an area of interest of a lithographic mask to produce an approximate prediction of the electromagnetic field from the area of interest. This is then applied as input to a machine learning model, which improves the electromagnetic field prediction from the quasi-rigorous simulation, thus yielding results which are closer to a fully-rigorous Maxwell simulation but without requiring the same computational load.

The machine learning model has been trained using training samples that include (a) the electromagnetic field predicted by the quasi-rigorous electromagnetic simulation, and (b) the corresponding ground-truth electromagnetic field predicted by a fully rigorous Maxwell solver, such as those based on Rigorous Coupled-Wave Analysis (RCWA) or Finite-Difference Time-Domain (FDTD) techniques.

In other aspects, the area of interest is partitioned into tiles. The quasi-rigorous electromagnetic simulation and machine learning model are applied to each tile to predict the electromagnetic field for each tile. These component fields are combined to produce the overall predicted field for the area of interest.

Other aspects include components, devices, systems, improvements, methods, processes, applications, computer readable mediums, and other technologies related to any of the above.

### BRIEF DESCRIPTION OF THE DRAWINGS

The disclosure will be understood more fully from the detailed description given below and from the accompanying figures of embodiments of the disclosure. The figures are used to provide knowledge and understanding of embodiments of the disclosure and do not limit the scope of the disclosure to these specific embodiments. Furthermore, the figures are not necessarily drawn to scale.

FIG. 1A depicts an extreme ultraviolet (EUV) lithography process suitable for use with embodiments of the present disclosure.

FIG. 1B depicts a flowchart for simulating a lithography process.

FIG. 2 depicts another flowchart for simulating a lithography process.

FIG. 3 depicts another flowchart for simulating a lithography process using commercially available EDA tools.

FIG. 4 depicts a flowchart for training a machine learning model.

FIG. 5 depicts a flowchart for inference using the trained machine learning model.

FIGS. 6A and 6B depict an example showing accuracy of some embodiments of the present disclosure.

FIG. 7 depicts a flowchart of various processes used during the design and manufacture of an integrated circuit in accordance with some embodiments of the present disclosure.

FIG. 8 depicts a diagram of an example computer system in which embodiments of the present disclosure may operate.

### DETAILED DESCRIPTION

Aspects of the present disclosure relate to lithography simulation using quasi-rigorous electromagnetic simulation and machine learning. Embodiments of the present disclosure combine less than rigorous physics-based modeling technology with machine learning augmentations to address the increasing accuracy requirement for modeling of advanced lithography nodes. While a fully-rigorous model would be desirable for such applications, fully rigorous Maxwell solvers require memory and runtime that scale almost exponentially with the area of the lithographic mask. Consequently, it is currently not practical for areas beyond a few microns by a few microns.

Conventionally, fully rigorous models may be used in combination with domain decomposition or other quasi-rigorous techniques to reduce the computational complexity at the cost of certain accuracy loss. Embodiments of the present disclosure improve the accuracies of such flows to much closer to the accuracy of fully rigorous models, while memory consumption maintains near the same level and runtime increases only marginally compared to conventional approaches. This allows more accurate simulation over a larger area or even for full-chip applications.

Due to the inherent approximations in domain decomposition based approaches, in which case higher-order interactions such as corner couplings are omitted, usually the resulting accuracy is not sufficient to meet the requirements of state-of-the-art lithography simulation. As described below, the drawbacks associated with those approximations may be mitigated and the actual physical effects recaptured through a machine learning (ML) sub-flow which may be embedded into a conventional lithography simulation flow. This embedded sub-flow is able to treat the non-trivial higher order interactions through machine learning based techniques.

Embodiments of the approach are compatible with existing simulation engines implemented in Sentaurus Lithography(S-Litho) from Synopsys, and may also be used with a wide range of lithography modeling and patterning technologies. Examples include:
Compatible with S-Litho High Performance (HP) mode solver and/or S-Litho High performance library (HPL) engine.
Applicable to modeling of any lithography patterns such as curvilinear mask patterns.
Applicable to advanced lithography technologies such as High-numerical aperture EUV (e.g., wavelengths of 13.3-13.7 nm) patterning.

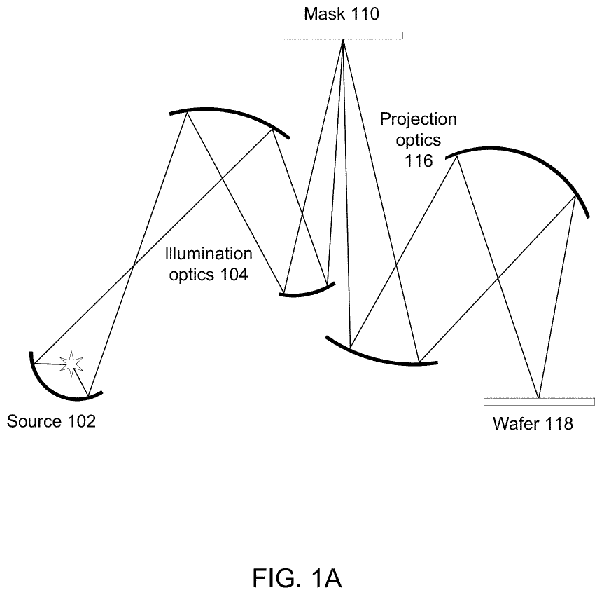

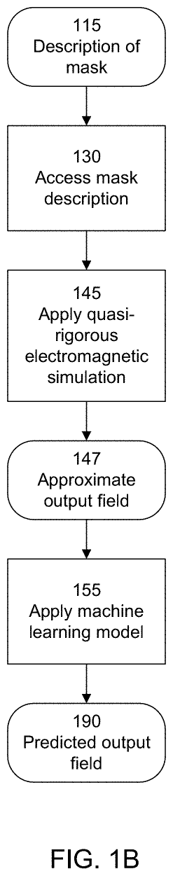

In more detail, FIG. 1A depicts an EUV lithography process suitable for use with embodiments of the present disclosure. In this system, a source 102 produces EUV light that is collected and directed by collection/illumination optics 104 to illuminate a mask 110. Projection optics 116 relay the pattern produced by the illuminated mask onto a wafer 118, exposing resist on the wafer according to the illumination pattern. The exposed resist is then developed, producing patterned resist on the wafer. This is used to fabricate structures on the wafer, for example through deposition, doping, etching or other processes.

In FIG. 1A, the light is in the EUV wavelength range, around 13.5 nm or in the range 13.3-13.7 nm. At these wavelengths, the components typically are reflective, rather than transmissive. The mask 110 is a reflective mask and the optics 104, 116 are also reflective and off-axis. This is just an example. Other types of lithography systems may also be used, including at other wavelengths including deep ultraviolet (DUV), using transmissive masks and/or optics, and using positive or negative resist.

FIG. 1B depicts a flowchart of a method for predicting an output electromagnetic field produced by a lithography process, such as the one shown in FIG. 1A. Using EUV lithography as an example, the source is an EUV source shaped by source masking and the lithographic mask is a multi-layer reflective mask. The lithographic mask may be described by the mask layout and stack material (i.e., the thickness and optical properties of different materials at different spatial positions x,y on the mask). The mask description 115 is accessed 130 by the computational lithography tool, which applies 145 a quasi-rigorous electromagnetic simulation technique, such as using domain decomposition techniques. The quasi-rigorous electromagnetic simulation 145 is less rigorous than a fully rigorous Maxwell solver, so it runs faster but produces less accurate results. This produces an approximate prediction 147 of the output electromagnetic field produced by the lithography process, based on the description of the lithographic mask. However, quasi-rigorous techniques may not be accurate enough, especially at smaller geometry nodes.

The approximate field 147 predicted by the quasi-rigorous technique is improved through use of a machine learning model 155. The machine learning model 155 has been trained to improve the results 147 from the quasi-rigorous simulation. Thus, the final result 190 is closer to the output electromagnetic field predicted by the fully rigorous Maxwell calculation.

The predicted electromagnetic field may be used to simulate a remainder of the lithography process (e.g., resist exposure and development), and the lithography configuration may be modified based on the simulation of the lithography process.

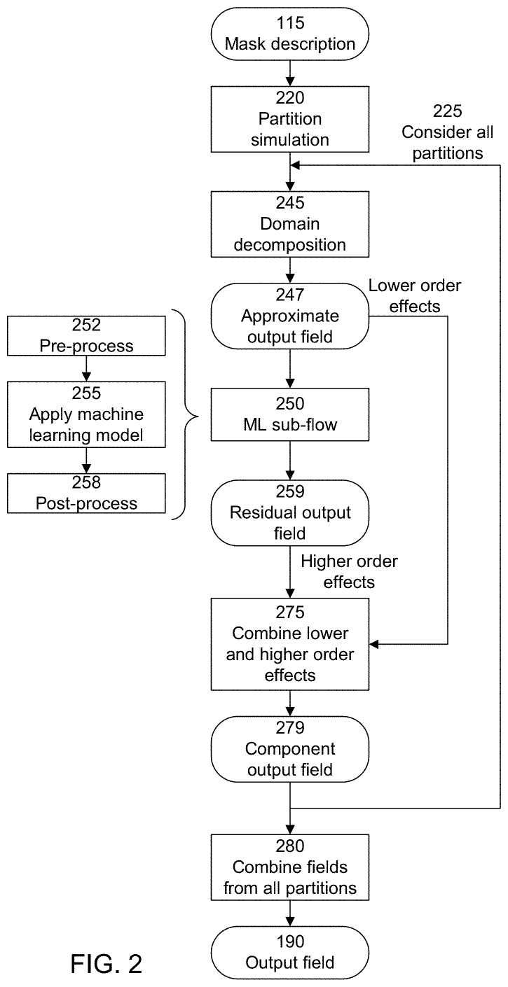

FIG. 2 depicts another flowchart for simulating a lithography process in accordance with some embodiments of the present disclosure. This flowchart is for a particular embodiment and contains more detail than FIG. 1B. In this example, the quasi-rigorous simulation is based on domain decomposition 245, and the simulation may be partitioned 220 into different pieces, and pre- and post-processing are used in the sub-flow 250 for the machine learning model 255.

The output field 190 is a function of the overall lithography configuration, which includes the source illumination and the lithographic mask. Rather than simulating the entire lithography configuration at once, the simulation may be partitioned 220 into smaller pieces, the output contributions from each partition is calculated (loop 225), and then these contributions are combined 280 to yield the total output field 190.

Different partitions may be used. In one approach, the lithographic mask is spatially partitioned. A mask of larger area may be partitioned into smaller tiles. The tiles may be overlapping in order to capture interactions between features that would otherwise be located on two separate tiles. The tiles themselves may also be partitioned into sets of predefined features, for example to accelerate the quasi-rigorous simulation 245. The contributions from the different features within a tile and from the different tiles are combined 280 to produce the total output field 190. In this way, the lithography process for the lithographic mask for an entire chip may be simulated.

The source illumination may also be partitioned. For example, the source itself may be spatially partitioned into different source areas. Alternatively, the source illumination may be partitioned into other types of components, such as plane waves propagating in different directions. The contributions from the different source components are also combined 280 to produce the total output field 190.

In one approach, different machine learning models 255 are used for different source components, but not for different tiles or features within tiles. Machine learning model A is used for all tiles and features illuminated by source component A, machine learning model B is used for all tiles and features illuminated by source component B, etc. The machine learning models will have been trained using different tiles and features, but the model 255 applied in FIG. 2 does not change as a function of the tile or feature. The model 255 is also independent of other process conditions, such as dose and defocus.

In FIG. 2, consideration 225 of the different partitions is shown as a loop. The partitioning may be implemented as loops or nested loops, and different orderings of the partitions may be used. Partitions may also be considered in parallel, rather than sequentially in loops. Hybrid approaches may also be used, where certain partitions are grouped together and processed at once, but the simulation loops through different groups.

In the following example, the processing of the inner steps 247-279 are discussed assuming that the mask has been partitioned into overlapping tiles and assuming that the source has also been partitioned into different components with a different machine learning model 255 used for different source components.

In FIG. 2, the quasi-rigorous electromagnetic simulation is based on domain decomposition 245. A fully rigorous Maxwell solver is a full-wave solution of Maxwell's equations in three dimensions without approximating assumptions. It considers all components of the electromagnetic field and solves the three-dimensional problem defined by Maxwell's equations, including coupling between all components of the field. In domain decomposition 245, the full three-dimensional problem is decomposed into several smaller problems of lower dimensionality. Each of these is solved using Maxwell's equations, and the resulting component fields are combined to yield the approximate solution.

For example, assume the mask is opaque but with a center square that is reflective. In the fully rigorous approach, Maxwell's equations are applied to this two-dimensional mask layout and solved for the resulting output field. In domain decomposition 245, the mask may be decomposed into a zero-dimensional component (i.e. some background signal that is constant across x and y) and two one-dimensional components: one with a reflective vertical stripe, and one with a reflective horizontal stripe. Maxwell's equations are applied to each component. The resulting output fields for the components are then combined to yield an approximation 247 of the output field.

In this example, coupling between x- and y-components is ignored. The domain decomposition 245 accounts for lower order effects such as the interaction between the two horizontal (or vertical) edges of the center square, but it provides only an approximation of higher order effects such as the interaction between a horizontal edge and vertical edge (corner coupling). The machine learning (ML) sub-flow 250 corrects the approximate field 247 to account for these higher order effects.

In FIG. 2, a tile description is used as input to the domain decomposition 245. The tile description may have dimensions 256×256×S, where the 256×256 are spatial coordinates x and y and ×S is the stack depth. The 256×256 may correspond to an area of 200 nm×200 nm. Thus, each pixel is significantly less than a wavelength. The stack depth may be the number of layers in the stack, where each layer is defined by a thickness and a dielectric constant. Applying the domain decomposition 245 yields an approximate output electromagnetic field 247. In this case, field 247 may have dimensions 256×256×8, where the 256×256 are spatial coordinates x and y and the ×8 are different polarization components of the field. In the domain decomposition 245, each component (e.g., vertical stripe and horizontal stripe) produces a component output field and these are combined to yield the approximate field 247.

In FIG. 2, the approximate output field 247 is applied to the ML sub-flow 250, which estimates the difference between the fully rigorous solution and the approximate solution 247. This difference is referred to as the residual output field 259, which in this example has dimensions 256×256×8. In this sub-flow 250, the approximate prediction 247 is pre-processed 252, applied 255 to the machine learning model and the output of the machine learning model is then post-processed 258. Examples of pre-processing 252 include the following: applying Fourier transform, balancing the channel dimension (the ×8 dimension) for example by changing the basis functions, scaling, and filtering. These may be performed to achieve better performance within the machine learning model 255. Post-processing 258 applies the inverse functions of pre-processing. The residual output field 259 is combined 270 with the approximate output field 247 to yield an improved prediction 279 of the output field for that tile. For example, when higher order interactions are neglected, the higher diffraction orders in k-space predicted for the approximate field 247 may be inaccurate. The residual output field 259 may include corrections to improve the prediction of the higher diffraction orders in output field 279.

This approach introduces a fast and closer to rigorous lithography simulation framework. It can provide simulation speed similar to conventional domain-decomposition based approaches, while delivering superior accuracy closer to that of a fully-rigorous Maxwell solver.

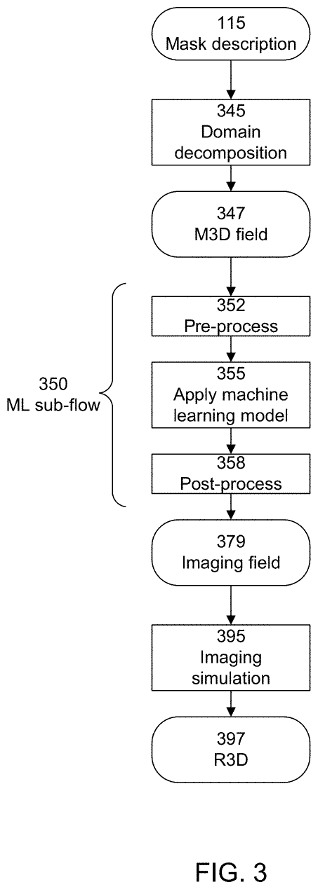

FIG. 3 depicts another flowchart for simulating a lithography process. A machine learning (ML) sub-flow 350 is tightly coupled into a physical simulation flow. The physical simulation flow 345 implements the domain decomposition, producing an intermediate spectral signal labeled M3D field 347. This corresponds to the approximate output field 147, 247 in FIGS. 1 and 2. The embedded ML sub-flow 350 first transforms the output 347 through a pre-ML processing block 352 to be used as direct input to a ML neural network 355, which in this example is a neural network. A post-ML processing block 358 transforms the inferenced results back to an imaging compatible signal labelled imaging field 379.

The last step in the example of FIG. 3 forwards the signal to the following imaging step 395 to produce rigorous 3D aerial images in photoresists (R3D 397). The imaging field 379 may also be used for other purposes. For example, simulation of the lithography process may be used to modify the design of the lithographic mask.

Within the ML sub-flow 350, the pre-processing step 352 takes intermediate spectral results 347 from the conventional mask simulation step 345 as input, and transforms those spectral data into an appropriate format which is numerically suitable for the ML neural network 355. The post-processing 358 applies the complementary procedure to transform the inferenced results from ML neural network output into spectral information usable by the rigorous vector imaging 395.

Comparing FIGS. 2 and 3, the combining of the approximate output field 247 with residual output field 259 is implemented within the ML sub-flow 350 of FIG. 3. For example, the machine learning model 355 may have a residual-learning type (ResNet) layer at the top level in the ML neural network 355.

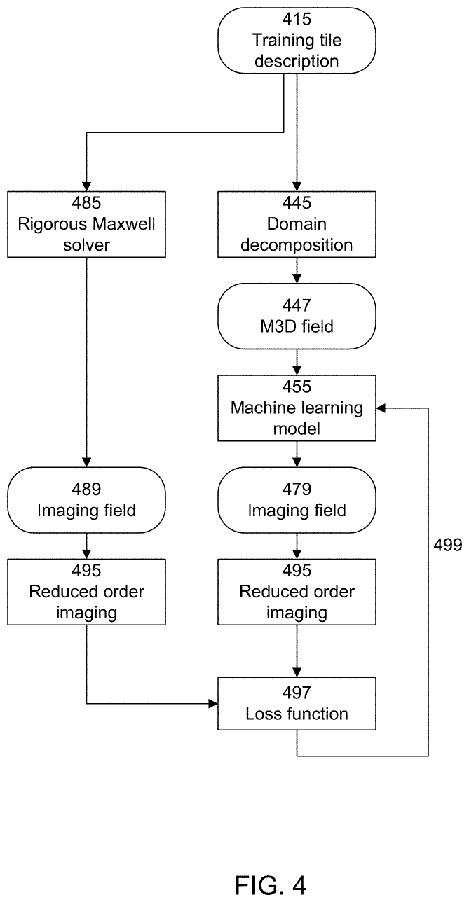

FIG. 4 depicts a flowchart for training a machine learning model. One issue in lithography modeling is 3D mask induced effects, such as pattern dependent defocus shift. In order for the machine learning model 455 to learn such physical effects, a custom loss function 497 may be used for training. In some embodiments, an independent Abbe imaging step is used as a good candidate to generate the custom loss function 497, since it may be integrated into a machine learning framework (e.g., Tensorflow). The imaging itself used for the loss function 497 should be fast and efficient. This is realized by a reduced-order imaging implementation 495 which assumes a simplified wafer stack with only a few imaging planes.

The machine learning model 455 is trained using a set of training tiles 415. During the training stage as depicted in FIG. 4, the same reduced-order imaging procedure is applied to two flows. The left flow contains a full rigorous Maxwell solver 485 (e.g., RCWA or FDTD approach), which produces an output field 489 that is considered to be ground-truth. The right flow contains a domain decomposition based solver (i.e., quasi-rigorous solver 445) and a machine learning model 455. It produces the output field 479, as described in FIG. 3. The two imaging fields 489, 479 are not compared directly. Rather, both fields are applied to reduced-order imaging 495 to produce corresponding images. In reduced-order imaging, the fields at only a few imaging planes are predicted. The output results of the imaging corresponding to those two flows are then subtracted to compute the loss function 497, where the subtraction is performed pixel-wise. A weighted sum of the intensity values per-pixel is returned 499 for back propagation of gradients in the machine learning model 455.

The training dataset 415 contain training samples (test patterns) that represent small tiles of possible patterns within the mask. For example, the tiles and training samples may be 256×256×8, where the 256×256 dimensions represent different spatial positions. The remaining ×8 dimension represents the field at the different spatial positions. In one approach, the training dataset includes a compilation of several hundred patterns, including basic line space patterns as well as some 2D patterns across different pitch sizes. The number of training patterns is less than the number of possible patterns for tiles of the same size. The training samples may be selected based on lithography characteristics. For example, certain patterns may be more commonly occurring or may be more difficult to simulate. As another example, the training dataset may incorporate some patterns that are specifically for the purpose of conserving certain known invariances and/or symmetries, e.g. some circular patterns for rotational symmetry, and the training may then enforce these.

The ground-truth images computed by the fully rigorous solvers for the loss function may be generated with a fixed grid (e.g., 256×256 pixels). The corresponding sampling window is chosen to take into account nearfield influence range. Therefore in each dimension for the sampling window, a physical length of 50˜60 wavelengths is used.

In this example, the ML neural network has a residual-learning type (ResNet) layer. It may also have an auto-encoder type or GAN (general adversarial network)-like network structure as the backbone within the ML neural network, in order to improve the shift-variance in lithography simulations. The model typically has a large number of layers: preferably more than 20, or even more than 50. After its training as described above, the machine learning model learns to decouple and extract the high order interaction terms (e.g. corner coupling) that is intrinsically missing from the less rigorous simulation. In addition, it also may remove some undesired phase distortion or perturbation from the results produced by a conventional domain decomposition based approach. Stated differently, using a machine learning approach does not imply that this approach entirely ignores the physics of scattering and lithography imaging, which is in fact statistically inferred through deep learning in a convolutional neural network by using a number of rigorously resolved images as ground truth in the training phase.

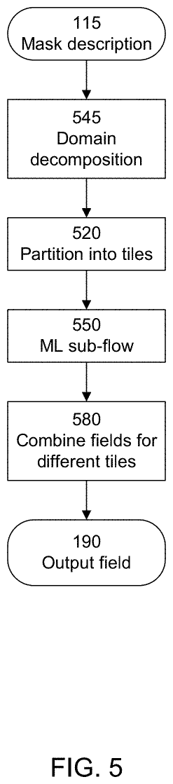

FIG. 5 depicts a flowchart for inference using the trained machine learning model. After the training phase is finished, the trained ML neural network 550 accepts a fixed image size while the input layout dimension can be quite large (up to hundreds of microns or larger). Therefore partitioning 520 and merging 580 operations are implemented at the ML neural network input and output stages respectively. In FIG. 5, the overall inference flow is shown including physical simulation by quasi-rigorous electromagnetic simulation 545 and inference by the ML model 550, as well as the layout partitioning 520 and merging 580 operations. The layout of the lithographic mask 115 is partitioned 520 into multiple tiles, preferably with a certain overlapping halo between adjacent tiles. In one approach, the overlapping halo is adapted automatically to be larger than the nearfield influence range, which is typically a few wavelengths. The quasi-rigorous electromagnetic simulation 545 and machine learning model 550 are applied to each tile to predict the electromagnetic field produced by that tile. The component fields are then combined 580 to produce the estimated field 190 from the full area being simulated.

In the inference stage of FIG. 5, the ML neural network 550 works together with a domain decomposition based solver 545 to re-capture the high order effects and approach fully-rigorous quality of results (QoR). The runtime overhead introduced by the ML inference is insignificant compared to the other non-ML part in the flow. Therefore the speed of the current flow is close to the conventional domain decomposition based approach.

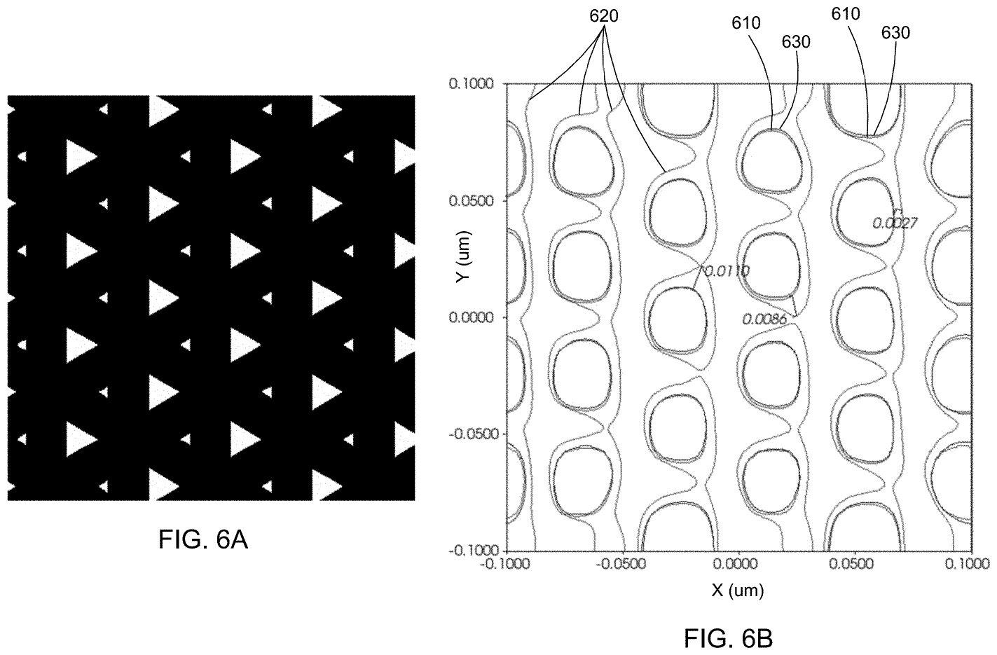

The machine learning augmentation has been tested successfully on various relevant lithographic patterns, including patterns subjected to optical proximity correction (OPC), curvilinear patterns, and patterns with different types of assist features. FIGS. 6A and 6B depict an example showing accuracy of some embodiments of the present disclosure. These figures demonstrate that this technology can be applied to small pitch patterns with exotic assist features and produce excellent results compared to results resolved by fully rigorous approaches. FIG. 6A shows the mask. The black areas are light absorbing material, and the white areas are transmissive or reflective depending on the mask technology.

FIG. 6B shows the resulting predictions of constant intensity contours in the aerial image. The contours 610 are the ground-truth, as predicted by the fully rigorous approach. The contours 620 are predicted by a conventional domain decomposition-based approach. The contours 630 are the conventional domain decomposition plus the machine learning augmentation. For such cases, conventional quasi-rigorous approaches alone 620 can fail badly and therefore cannot be relied upon.

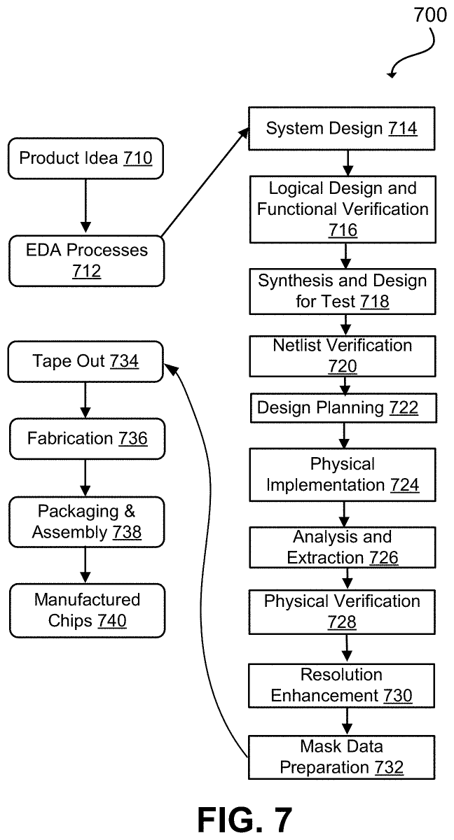

FIG. 7 illustrates an example set of processes 700 used during the design, verification, and fabrication of an article of manufacture such as an integrated circuit to transform and verify design data and instructions that represent the integrated circuit. Each of these processes can be structured and enabled as multiple modules or operations. The term ‘EDA’ signifies the term ‘Electronic Design Automation.’ These processes start with the creation of a product idea 710 with information supplied by a designer, information which is transformed to create an article of manufacture that uses a set of EDA processes 712. When the design is finalized, the design is taped-out 734, which is when artwork (e.g., geometric patterns) for the integrated circuit is sent to a fabrication facility to manufacture the mask set, which is then used to manufacture the integrated circuit. After tape-out, a semiconductor die is fabricated 736 and packaging and assembly processes 738 are performed to produce the finished integrated circuit 740.

Specifications for a circuit or electronic structure may range from low-level transistor material layouts to high-level description languages. A high-level of abstraction may be used to design circuits and systems, using a hardware description language (‘HDL’) such as VHDL, Verilog, SystemVerilog, SystemC, MyHDL or OpenVera. The HDL description can be transformed to a logic-level register transfer level (‘RTL’) description, a gate-level description, a layout-level description, or a mask-level description. Each lower abstraction level that is a less abstract description adds more useful detail into the design description, for example, more details for the modules that include the description. The lower levels of abstraction that are less abstract descriptions can be generated by a computer, derived from a design library, or created by another design automation process. An example of a specification language at a lower level of abstraction language for specifying more detailed descriptions is SPICE, which is used for detailed descriptions of circuits with many analog components. Descriptions at each level of abstraction are enabled for use by the corresponding tools of that layer (e.g., a formal verification tool). A design process may use a sequence depicted in FIG. 7. The processes described by be enabled by EDA products (or tools).

During system design 714, functionality of an integrated circuit to be manufactured is specified. The design may be optimized for desired characteristics such as power consumption, performance, area (physical and/or lines of code), and reduction of costs, etc. Partitioning of the design into different types of modules or components can occur at this stage.

During logic design and functional verification 716, modules or components in the circuit are specified in one or more description languages and the specification is checked for functional accuracy. For example, the components of the circuit may be verified to generate outputs that match the requirements of the specification of the circuit or system being designed. Functional verification may use simulators and other programs such as testbench generators, static HDL checkers, and formal verifiers. In some embodiments, special systems of components referred to as ‘emulators’ or ‘prototyping systems’ are used to speed up the functional verification.

During synthesis and design for test 718, HDL code is transformed to a netlist. In some embodiments, a netlist may be a graph structure where edges of the graph structure represent components of a circuit and where the nodes of the graph structure represent how the components are interconnected. Both the HDL code and the netlist are hierarchical articles of manufacture that can be used by an EDA product to verify that the integrated circuit, when manufactured, performs according to the specified design. The netlist can be optimized for a target semiconductor manufacturing technology. Additionally, the finished integrated circuit may be tested to verify that the integrated circuit satisfies the requirements of the specification.

During netlist verification 720, the netlist is checked for compliance with timing constraints and for correspondence with the HDL code. During design planning 722, an overall floor plan for the integrated circuit is constructed and analyzed for timing and top-level routing.

During layout or physical implementation 724, physical placement (positioning of circuit components such as transistors or capacitors) and routing (connection of the circuit components by multiple conductors) occurs, and the selection of cells from a library to enable specific logic functions can be performed. As used herein, the term ‘cell’ may specify a set of transistors, other components, and interconnections that provides a Boolean logic function (e.g., AND, OR, NOT, XOR) or a storage function (such as a flipflop or latch). As used herein, a circuit ‘block’ may refer to two or more cells. Both a cell and a circuit block can be referred to as a module or component and are enabled as both physical structures and in simulations. Parameters are specified for selected cells (based on ‘standard cells’) such as size and made accessible in a database for use by EDA products.

During analysis and extraction 726, the circuit function is verified at the layout level, which permits refinement of the layout design. During physical verification 728, the layout design is checked to ensure that manufacturing constraints are correct, such as DRC constraints, electrical constraints, lithographic constraints, and that circuitry function matches the HDL design specification. During resolution enhancement 730, the geometry of the layout is transformed to improve how the circuit design is manufactured.

During tape-out, data is created to be used (after lithographic enhancements are applied if appropriate) for production of lithographic masks. During mask data preparation 732, the ‘tape-out’ data is used to produce lithographic masks that are used to produce finished integrated circuits.

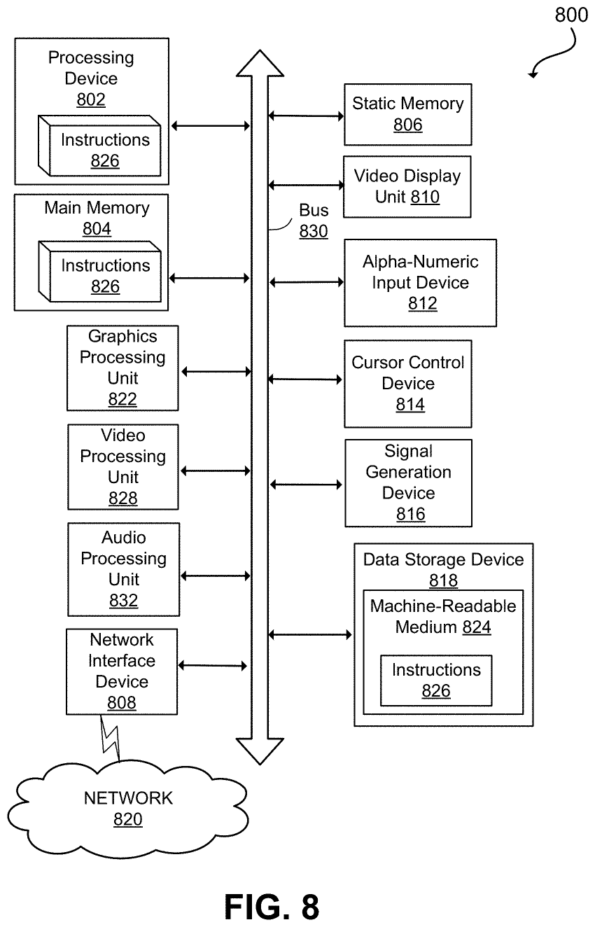

A storage subsystem of a computer system (such as computer system 800 of FIG. 8) may be used to store the programs and data structures that are used by some or all of the EDA products described herein, and products used for development of cells for the library and for physical and logical design that use the library.

FIG. 8 illustrates an example machine of a computer system 800 within which a set of instructions, for causing the machine to perform any one or more of the methodologies discussed herein, may be executed. In alternative implementations, the machine may be connected (e.g., networked) to other machines in a LAN, an intranet, an extranet, and/or the Internet. The machine may operate in the capacity of a server or a client machine in client-server network environment, as a peer machine in a peer-to-peer (or distributed) network environment, or as a server or a client machine in a cloud computing infrastructure or environment.

The machine may be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 800 includes a processing device 802, a main memory 804 (e.g., read-only memory (ROM), flash memory, dynamic random access memory (DRAM) such as synchronous DRAM (SDRAM), a static memory 806 (e.g., flash memory, static random access memory (SRAM), etc.), and a data storage device 818, which communicate with each other via a bus 830.

Processing device 802 represents one or more processors such as a microprocessor, a central processing unit, or the like. More particularly, the processing device may be complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 802 may also be one or more special-purpose processing devices such as an application specific integrated circuit (ASIC), a field programmable gate array (FPGA), a digital signal processor (DSP), network processor, or the like. The processing device 802 may be configured to execute instructions 826 for performing the operations and steps described herein.

The computer system 800 may further include a network interface device 808 to communicate over the network 820. The computer system 800 also may include a video display unit 810 (e.g., a liquid crystal display (LCD) or a cathode ray tube (CRT)), an alphanumeric input device 812 (e.g., a keyboard), a cursor control device 814 (e.g., a mouse), a graphics processing unit 822, a signal generation device 816 (e.g., a speaker), graphics processing unit 822, video processing unit 828, and audio processing unit 832.

The data storage device 818 may include a machine-readable storage medium 824 (also known as a non-transitory computer-readable medium) on which is stored one or more sets of instructions 826 or software embodying any one or more of the methodologies or functions described herein. The instructions 826 may also reside, completely or at least partially, within the main memory 804 and/or within the processing device 802 during execution thereof by the computer system 800, the main memory 804 and the processing device 802 also constituting machine-readable storage media.

In some implementations, the instructions 826 include instructions to implement functionality corresponding to the present disclosure. While the machine-readable storage medium 824 is shown in an example implementation to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine and the processing device 802 to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm may be a sequence of operations leading to a desired result. The operations are those requiring physical manipulations of physical quantities. Such quantities may take the form of electrical or magnetic signals capable of being stored, combined, compared, and otherwise manipulated. Such signals may be referred to as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the present disclosure, it is appreciated that throughout the description, certain terms refer to the action and processes of a computer system, or similar electronic computing device, that manipulates and transforms data represented as physical (electronic) quantities within the computer system's registers and memories into other data similarly represented as physical quantities within the computer system memories or registers or other such information storage devices.

The present disclosure also relates to an apparatus for performing the operations herein. This apparatus may be specially constructed for the intended purposes, or it may include a computer selectively activated or reconfigured by a computer program stored in the computer. Such a computer program may be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various other systems may be used with programs in accordance with the teachings herein, or it may prove convenient to construct a more specialized apparatus to perform the method. In addition, the present disclosure is not described with reference to any particular programming language. It will be appreciated that a variety of programming languages may be used to implement the teachings of the disclosure as described herein.

The present disclosure may be provided as a computer program product, or software, that may include a machine-readable medium having stored thereon instructions, which may be used to program a computer system (or other electronic devices) to perform a process according to the present disclosure. A machine-readable medium includes any mechanism for storing information in a form readable by a machine (e.g., a computer). For example, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing disclosure, implementations of the disclosure have been described with reference to specific example implementations thereof. It will be evident that various modifications may be made thereto without departing from the broader spirit and scope of implementations of the disclosure as set forth in the following claims. Where the disclosure refers to some elements in the singular tense, more than one element can be depicted in the figures and like elements are labeled with like numerals. The disclosure and drawings are, accordingly, to be regarded in an illustrative sense rather than a restrictive sense.

What is claimed is:

1. A method comprising:
accessing a description of a lithographic mask;
applying a domain decomposition electromagnetic simulation to produce an approximate prediction of an output field resulting from the lithographic mask; and
applying, by a processor, the approximate prediction as input to a machine learning model to produce an improved prediction of the output field, wherein the machine learning model accounts for higher order effects that are approximated by the domain decomposition.

2. The method of claim 1 wherein the input applied to the machine learning model comprises three-dimensional data, in which two of the dimensions represent spatial dimensions of the lithographic mask and the third dimension represents polarization components for the output field.

3. The method of claim 1 wherein the approximate prediction produced by the domain decomposition electromagnetic simulation comprises coupling between individual components of the output field, and the machine learning model improves the prediction of the coupling.

4. The method of claim 1 wherein the approximate prediction produced by the domain decomposition electromagnetic simulation comprises higher diffraction orders in k-space, and the machine learning model improves the prediction of the higher diffraction orders.

5. The method of claim 1 further comprising:
partitioning the lithographic mask into a plurality of tiles;
applying the domain decomposition electromagnetic simulation and machine learning model to the tiles to produce improved predictions for the tiles; and
combining the improved predictions for the plurality of tiles to produce the improved prediction for the lithographic mask.

6. The method of claim 5 wherein the lithographic mask is for an entire chip.

7. The method of claim 1 further comprising:
partitioning a source illumination into multiple components;
for each component, applying the domain decomposition electromagnetic simulation and machine learning model to produce improved prediction for that component, wherein different machine learning models are used for different components; and
combining the improved predictions for the multiple components to produce the improved prediction for the lithographic mask.

8. A system comprising a memory storing instructions; and a processor, coupled with the memory and to execute the instructions, the instructions when executed cause the processor to:
access a description of a lithographic mask;
apply a quasi-rigorous electromagnetic simulation to produce an approximate prediction of an output field resulting from the lithographic mask, wherein the quasi-rigorous electromagnetic simulation is less rigorous than a fully rigorous Maxwell solver; and
apply the approximate prediction as input to a machine learning model to produce an improved prediction of the output field.

9. The system of claim 8 wherein the instructions further cause the processor to:
balance the input applied to the machine learning model and/or scale the input applied to the machine learning model.

10. The system of claim 8 wherein the machine learning model comprises a residual-learning type layer.

11. The system of claim 10 wherein the machine learning model further comprises an auto-encoder or GAN type model.

12. The system of claim 8 wherein the machine learning model comprises at least 20 layers.

13. The system of claim 8 wherein the lithographic mask contains features that are smaller than a wavelength of an illuminating source.

14. The system of claim 8 wherein source illumination for the lithographic mask is an extreme ultraviolet (EUV) or deep ultraviolet (DUV) illumination.

15. The system of claim 8 the instructions further cause the processor to:
simulate a remainder of a lithography process based on the improved prediction of the output field; and
modify the lithographic mask based on the simulation of the lithography process.

16. A non-transitory computer readable medium comprising stored instructions, which when executed by a processor, cause the processor to:
access a description of a lithographic mask;
apply a domain decomposition electromagnetic simulation to produce an approximate prediction of an output field resulting from the lithographic mask; and
apply the approximate prediction as input to a machine learning model to produce an improved prediction of the output field, wherein the machine learning model accounts for higher order effects that are approximated by the domain decomposition.

17. The non-transitory computer readable medium of claim 16 wherein the machine learning model has been trained using a training set of training tiles, and ground-truth for the training is based on output fields produced by a fully rigorous Maxwell solver for the individual training tiles.

18. The non-transitory computer readable medium of claim 17 wherein the training set contains not more than 1000 different training tiles.

19. The non-transitory computer readable medium of claim 17 wherein the training set includes training tiles with known symmetry and training of the machine learning model enforces the known symmetry.

20. The non-transitory computer readable medium of claim 17 wherein the training is further based on a loss function comparing images predicted by (a) the fully rigorous Maxwell solver, and (b) the domain decomposition electromagnetic simulation and the machine learning model.
